(19) United States
(12) Patent Application Publication
(10) Pub. No.: US 2014/0360768 A1
(43) Pub. Date: Dec. 11, 2014

(54) SEMICONDUCTOR PACKAGE BOARD AND METHOD FOR MANUFACTURING THE SAME

(71) Applicant: SAMSUNG ELECTRO-MECHANICS CO., LTD., Suwon-Si (KR)

(72) Inventor: Myung Sam KANG, Suwon-Si (KR)

(73) Assignee: SAMSUNG ELECTRO-MECHANICS CO., LTD., Suwon-Si (KR)

(21) Appl. No.: 14/296,126

(22) Filed: Jun. 4, 2014

(30) Foreign Application Priority Data
Jun. 7, 2013 (KR) 10-2013-0065267

(51) Int. Cl. H05K 1/11; H05K 3/40; H05K 3/46; H05K 3/10

(52) U.S. Cl. CPC H05K 1/111; H05K 3/10; H05K 3/4038; H05K 3/4644; H05K 3/4007
USPC 174/261; 29/846; 29/852

(57) ABSTRACT

Disclosed herein are a semiconductor package board and a method for manufacturing the same. The semiconductor package board according to a preferred embodiment of the present invention includes an insulating layer; a first circuit layer formed on one surface of the insulating layer and including a bump pad; a post bump formed on the bump pad and formed integrally with the bump pad; and a first solder resist layer formed on the insulating layer and the first circuit layer and having a first opening part exposing the post bump and bump pad formed thereon.

### CROSS REFERENCE TO RELATED APPLICATION

This application claims the benefit of Korean Patent Application No. 10-2013-0065267, filed on Jun. 7, 2013, entitled “Semiconductor Package Board and Method for Manufacturing the Same”, which is hereby incorporated by reference in its entirety into this application.

### BACKGROUND OF THE INVENTION

1. Technical Field

The present invention relates to a semiconductor package board and a method for manufacturing the same.

2. Description of the Related Art

In accordance with development of an electronic industry, a usage of a semiconductor package in which a semiconductor chip is mounted on an electronic device has been rapidly increased. Most of the semiconductor packages have a board on chip (BOC) structure formed by connecting the semiconductor chip and a board to each other using a wire bonding. The board used for the BOC structure has a terminal of the semiconductor chip disposed at the center thereof for characteristics of the semiconductor chip and is formed in a structure capable of being directly connected to the terminal to increase a signal processing speed. That is, the semiconductor chip is attached below the board, and a slot is formed in a portion at which the terminal is disposed, thereby making it possible to perform the wire bonding between the semiconductor chip and the board through the slot.

As a technology for manufacturing a semiconductor is very rapidly developed, capacity of the semiconductor package has been also increased and an increase in the signal processing speed has been required. Due to the increase in the capacity of the semiconductor package, the semiconductor package having the BOC structure is changed from a single layer to a multi-layer, thereby causing signal loss in a wire.

In order to increase the signal processing speed, the semiconductor package uses a flip chip bonding structure (see U.S. Pat. No. 6,177,731). In this case, the semiconductor package having the flip chip bonding structure has bad flowability of an underfill material due to a gap lack between the board and the semiconductor chip. In addition, the semiconductor package having the flip chip bonding structure also has a problem with respect to connection reliability between the board and the semiconductor chip.

### SUMMARY OF THE INVENTION

The present invention has been made in an effort to provide a semiconductor package board capable of improving flowability of underfill, and a method for manufacturing the same.

The present invention has been made in an effort to provide a semiconductor package board capable of improving connection reliability between the semiconductor chip and the board, and a method for manufacturing the same.

The present invention has been made in an effort to provide a semiconductor package board capable of improving electrical characteristics for a high speed signal, and a method for manufacturing the same.

According to a preferred embodiment of the present invention, there is provided a semiconductor package board including: an insulating layer; a first circuit layer formed on one surface of the insulating layer and including a bump pad; a post bump formed on the bump pad and formed integrally with the bump pad; and a first solder resist layer formed on the insulating layer and the first circuit layer and having a first opening part exposing the post bump and the bump pad formed thereon.

The bump pad and the post bump may be made of the same material as each other.

The semiconductor package board may further include a first surface treatment layer formed on the bump pad and the post bump exposed by the first opening part.

The semiconductor package board may further include a second circuit layer formed on the other surface of the insulating layer and including a connection pad.

The semiconductor package board may further include a through via penetrating through the insulating layer to electrically connect the first circuit layer and the second circuit layer to each other.

The through via may electrically connect the bump pad and the connection pad to each other.

The semiconductor package board may further include a second solder resist layer formed on the other surface of the insulating layer and the second circuit layer and having a second opening part exposing the connection pad formed thereon.

The semiconductor package board may further include a second surface treatment layer formed on the connection pad exposed by the second opening part.

The post bump may be formed to be protruded from one surface of the first solder resist layer.

According to another preferred embodiment of the present invention, there is provided a method for manufacturing a semiconductor package board, the method including: preparing an insulating layer; forming a first circuit layer including a bump pad on one surface of the insulating layer; forming a post bump on the bump pad; and forming a first solder resist layer including a first opening part exposing the post bump and the bump pad.

In the forming of the post bump, the post bump may be made of the same material as the bump pad.

The method may further include, after the forming of the first solder resist layer, forming a first surface treatment layer on the bump pad and the post bump exposed by the first opening part.

The forming of the first circuit layer may further include forming a second circuit layer including a connection pad on the other surface of the insulating layer.

The forming of the first circuit layer may further include forming a through via penetrating through the insulating layer to electrically connect the first circuit layer and the second circuit layer to each other.

The through via may be formed to electrically connect the bump pad and the connection pad to each other.

The method may further include, after the forming of the second circuit layer, forming a second solder resist layer formed on the other surface of the insulating layer and the second circuit layer and having a second opening part exposing the connection pad formed thereon.

The method may further include, after the forming of the second solder resist layer, forming a second surface treatment layer on the connection pad exposed by the second opening part.

The method may further include, after the foaming of the second circuit layer, forming a solder ball on the connection pad.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a view illustrating a semiconductor package board according to a preferred embodiment of the present invention; and

FIGS. 2 to 17 are views illustrating a method for manufacturing a semiconductor package board according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, a preferred embodiment of the present invention will be described in detail with reference to the accompanying drawings.

Semiconductor Package Board

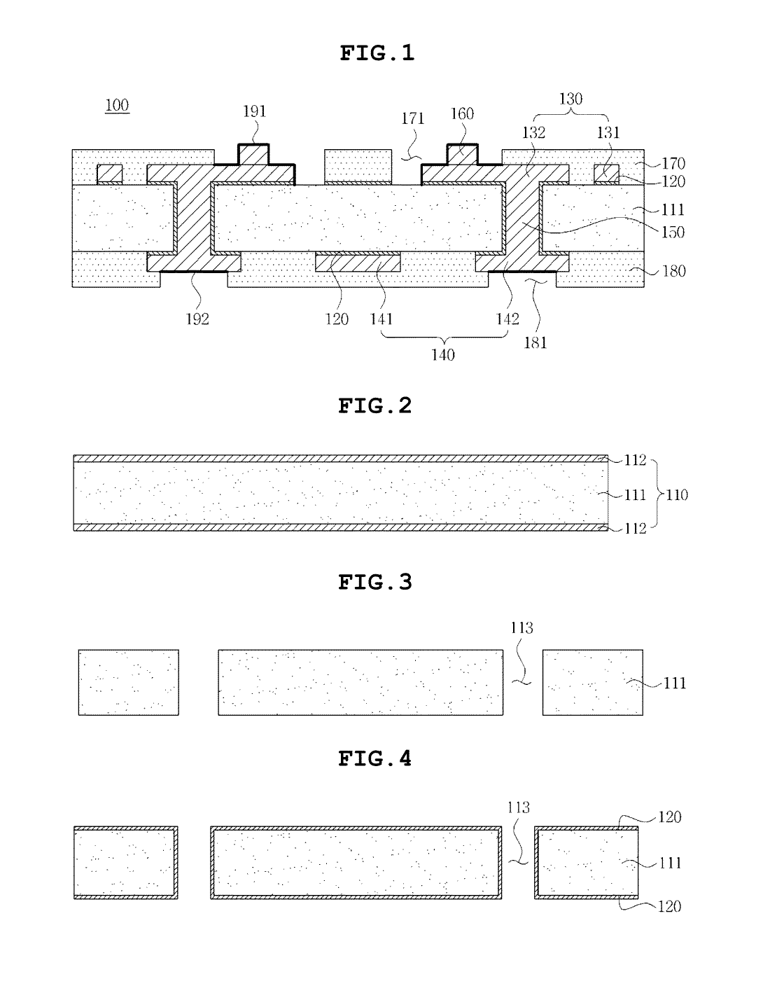

FIG. 1 is a view illustrating a semiconductor package board according to a preferred embodiment of the present invention.

Referring to FIG. 1, a semiconductor package board 100 may include an insulating layer 111, a first circuit layer 130, a second circuit layer 140, a post bump 160, a through via 150, a first solder resist layer 170, a second solder resist layer 180, a first surface treatment layer 191, and a second surface treatment layer 192.

The insulating layer 111 may be a resin insulating layer used as the insulating layer of a printed circuit board. In addition, the insulating layer 111 may be a ceramic insulating layer used as the insulating layer of a semiconductor board. The resin insulating layer may be a thermosetting resin such as an epoxy resin or thermoplastic resin such as polyimide. Alternatively, the resin insulating layer may be a resin in which a reinforcement material such as a glass fiber or an inorganic filler is impregnated in the epoxy resin. For example, the resin insulating layer may be prepreg. Alternatively, as the resin insulating layer, a photocurable resin, or the like may be used. However, the resin insulating layer is not particularly limited thereto.

Although the preferred embodiment of the present invention illustrates a case in which the insulating layer 111 is formed as a single layer, the present invention is not limited thereto. That is, the insulating layer 111 may have one or more internal circuit layers (not shown) further formed therein.

The first circuit layer 130 may be formed on one surface of the insulating layer 111. The first circuit layer 130 may include a first circuit pattern 131 and a bump pad 132. The bump pad 132 may be electrically connected to a semiconductor chip (not shown) through the post bump 160. The bump pad 132 according to the preferred embodiment of the present invention may be formed in a peripheral type form.

The first circuit layer 130 may be made of an electrical conductive metal. For example, the first circuit layer 130 may be made of copper. However, a material of the first circuit layer 130 is not limited to copper. The material of the first circuit layer 130 may be used without being limited as long as it is used as the conductive metal for a circuit in a circuit board field.

The second circuit layer 140 may be formed on the other surface of the insulating layer 111. The second circuit layer 140 may include a second circuit pattern 141 and a connection pad 142. The connection pad 142 may be directly connected to an external connecting terminal (not shown). In this case, the external connecting terminal (not shown) may be a solder ball. The second circuit layer 140 may be made of an electrical conductive metal. For example, the second circuit layer 140 may be made of copper. However, a material of the second circuit layer 140 is not limited to copper. The material of the second circuit layer 140 may be used without being limited as long as it is used as the conductive metal for a circuit in a circuit board field.

The through via 150 may be formed to penetrate through the insulating layer 111. The through via 150 may be formed to electrically conduct between the first circuit layer 130 formed on one surface of the insulating layer 111 and the second circuit layer 140 formed on the other surface of the insulating layer 111. For example, the through via 150 may electrically connect the bump pad 132 and the connection pad 142 to each other.

The post bump 160 may be formed on the bump pad 132. The post bump 160 may be flip-chip-bonded to the semiconductor chip (not shown) to be mounted on the semiconductor package board 100. The post bump 160 may be made of the same material as the first circuit layer 130. Particularly, the post bump 160 may be made of the same material as the bump pad 132.

A seed layer 120 may be formed between the first circuit layer 130 and the insulating layer 111, between the second circuit layer 140 and the insulating layer 111, and between the through via 150 and the insulating layer 111. The seed layer 120 may be selectively formed depending on a method for forming the first circuit layer 130, the second circuit layer 140, and the through via 150.

The first solder resist layer 170 may be formed on one surface of the insulating layer 111 and on the first circuit layer 130. The first solder resist layer 170 may be formed to protect and electrically insulate the first circuit layer 130. The first solder resist layer 170 may be formed to bury the first circuit pattern 131. The first solder resist layer 170 may include a first opening part 171 exposing the post bump 160 to the outside. The first opening part 171 may expose the post bump 160 as well as the bump pad 132 to the outside. A degree of exposing the bump pad 132 by the first opening part 171 may be easily changed by those skilled in the art.

The second solder resist layer 180 may be formed on the other surface of the insulating layer 111 and on the second circuit layer 140. The second solder resist layer 180 may be formed to protect and electrically insulate the second circuit layer 140. The second solder resist layer 180 may be formed to bury the second circuit pattern 141. The second solder resist layer 180 may include a second opening part 181 exposing the connection pad 142 to the outside.

The first surface treatment layer 191 may be formed on the post bump 160 and the bump pad 132 exposed by the first opening part 171 of the first solder resist layer 170. The second surface treatment layer 192 may be formed on the connection pad 142 exposed by the second opening part 181 of the second solder resist layer 180.

The first surface treatment layer 191 and the second surface treatment layer 192 are not particularly limited as long as they are known in the art. For example, the first surface treatment layer 191 and the second surface treatment layer 192 may be formed by an electro gold plating method, an immersion gold plating method, an organic solderability preservative (OSP) method or an immersion tin plating method, an immersion silver plating method, a direct immersion gold plating (DIG) method, a hot air solder leveling (HASL) method, or the like, for example.

The first surface treatment layer 191 and the second surface treatment layer 192 may be selectively formed by those skilled in the art.

According to the preferred embodiment of the present invention, the post bump 160 may be formed to be protruded from one surface of the first solder resist layer 170. A gap between the semiconductor chip (not shown) to be mounted and the semiconductor package board 100 may be secured by the post bump 160 formed as described above. Therefore, by securing a sufficient gap, upon the underfilling, flowability of an underfill material between the semiconductor package board 100 and the semiconductor chip (not shown) may be improved. In addition, upon the flip-chip-bonding, the post bump 160 of the semiconductor package board 100 may be directly connected to the bump or the pad of the semiconductor chip (not shown). As a result, connection reliability may be further improved as compared to the preferred art in which only the semiconductor chip (not shown) contacts the semiconductor package. In addition, since a separate gold plating lead line needs not to be formed due to improved connection reliability, noise occurrence caused by the gold plating lead line may be removed. As a result, signal loss caused by the noise occurrence may be minimized, thereby making it possible to improve electrical characteristics for a high speed signal.

Method for Manufacturing Semiconductor Package Board

FIGS. 2 to 17 are views illustrating a method for manufacturing a semiconductor package board according to a preferred embodiment of the present invention.

Referring to FIG. 2, a base board 110 is provided. According to the preferred embodiment of the present invention, the base board 110 may be a copper clad laminate (CCL) having an insulating layer 111 and copper foils 112 laminated on both surfaces of the insulating layer 111. However, the use of the copper clad laminate as the base board 110 is merely an exemplary embodiment, the present invention is not limited thereto. That is, the base board 110 may be a composite polymer resin generally used as an interlayer insulating material. For example, the printed circuit board may be manufactured to be thinner by employing prepreg as the base board 110. Alternatively, a fine circuit may be easily implemented by employing an Ajinomoto build up film (ABF) as the base board 110. In addition to this, the base board 110 may be made of an epoxy based resin such as FR-4, bismaleimide triazine, or the like, but the present invention is not particularly limited thereto.

In addition, although the preferred embodiment of the present invention illustrates a case in which the base board 110 is foamed of a single insulating layer, the present invention is not limited thereto. That is, the base substrate 110 may include one or more insulating layers and internal circuit layers.

Referring to FIG. 3, a through via hole 113 may be formed in the insulating layer 111. First, the copper foils 112 (see FIG. 2) formed on the base board 110 (see FIG. 2) may be removed. The copper foils 112 (see FIG. 2) may be removed by a typical etching method. The through via hole 113 may be formed in the insulating layer 111 from which the copper foils 112 (see FIG. 2) are removed, as described above. The through via hole 113 may be formed to penetrate through both surfaces of the insulating layer 111. The through via hole 113 formed as described above may be provided with a through via for electrical conduction between circuit layers formed on both surfaces of the insulating layer 111 later on. The through via hole 113 may be formed using a CNC drill, a laser drill, or the like.

Referring to FIG. 4, a seed layer 120 may be formed on the insulating layer 111. The seed layer 120 may be formed on both surfaces of the insulating layer 111 as well as on an inner wall of the through via hole 113. The seed layer 120 may be formed to serve as a lead line for electro plating. A method for forming the seed layer 120 is not particularly limited, but may be performed by a typical method known in the art. For example, the seed layer 120 may be formed by a wet plating method such as an electroless plating method or a dry plating method such as a sputtering method. The seed layer 120 may be made of an electrically conductive metal. For example, the seed layer 120 may be made of copper. However, a material of the seed layer 120 is not limited to copper.

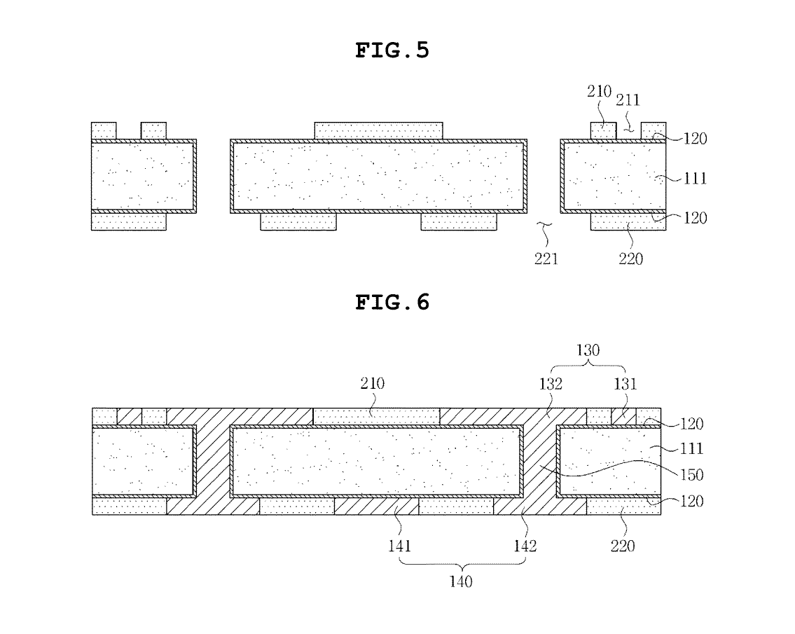

Referring to FIG. 5, a first plating resist 210 and a second plating resist 220 may be formed on the seed layer 120.

The first plating resist 210 may be formed on the seed layer 120 formed on one surface of the insulating layer 111. The first plating resist 210 may be patterned so that a first plating opening part 211 exposing a region on which a first circuit layer 130 is to be formed later on is formed.

The second plating resist 220 may be formed on the seed layer 120 formed on the other surface of the insulating layer 111. The second plating resist 220 may be patterned so that a second plating opening part 221 exposing a region on which a second circuit layer 140 is to be foamed later on is formed.

For example, the first plating resist 210 and the second plating resist 220 may be formed of a dry film. In addition, the first plating opening part 211 and the second plating opening part 221 may be patterned by exposing and developing the dry film.

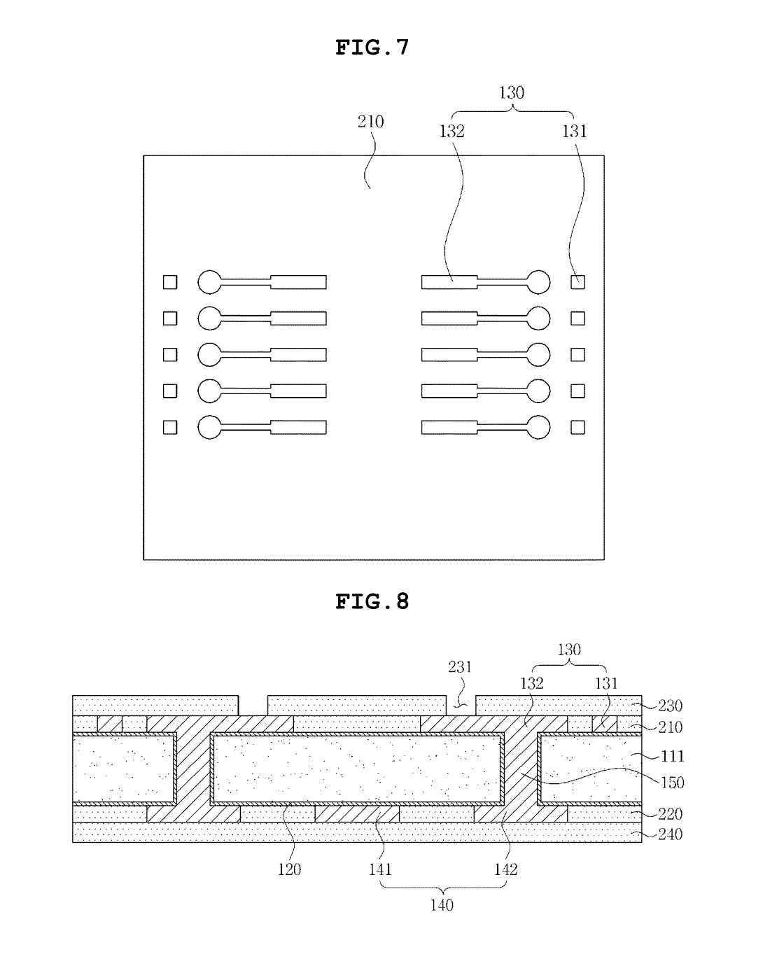

Referring to FIGS. 6 and 7, the first and second circuit layers 130 and 140 may be formed on the seed layer 120.

The first circuit layer 130 may be formed on the first plating opening part 211 (see FIG. 5) of the first plating resist 210. In addition, the second circuit layer 140 may be formed on the second plating opening part 221 (see FIG. 5) of the second plating resist 220. The first circuit layer 130 and the second circuit layer 140 may be made of an electrically conductive metal. For example, the first circuit layer 130 and the second circuit layer 140 may be made of copper. However, materials of the first circuit layer 130 and the second circuit layer 140 are not limited to copper. The materials of the first circuit layer 130 and the second circuit layer 140 may be used without being limited as long as they are used as the conductive metal for a circuit in a circuit board field.

The first circuit layer 130 and the second circuit layer 140 may be formed by the electro plating method using the seed layer 120 as the lead line.

Although the preferred embodiment of the present invention illustrates the electroless plating method and the electro plating method as the method for forming the first circuit layer 130 and the second circuit layer 140, the present invention is not limited thereto. That is, the method for forming the first circuit layer 130 and the second circuit layer 140 may be used without being limited as long as it is a typical method for forming the circuit layer.

The first circuit layer 130 formed as described above may include a first circuit pattern 131 and a bump pad 132. The bump pad 132 may be electrically connected to a semiconductor chip (not shown). The bump pad 132 according to the preferred embodiment of the present invention may be formed in a peripheral type form, as shown in FIG. 7.

In addition, the second circuit layer 140 may include a second circuit pattern 141 and a connection pad 142. The connection pad 142 may be directly connected to an external connecting terminal (not shown). In this case, the external connecting terminal (not shown) may be a solder ball.

When the first circuit layer 130 and the second circuit layer 140 are formed as described above, the electro plating may be simultaneously performed on the through via hole 113 (see FIG. 5). Therefore, a through via 150 may be formed in the through via hole 113 (see FIG. 5). The through via 150 may electrically connect the first circuit layer 130 and the second circuit layer 140 to each other. For example, the through via 150 may electrically connect the bump pad 132 of the first circuit layer 130 and the connection pad 142 of the second circuit layer 140 to each other.

Referring to FIGS. 8 to 10, a third plating resist 230 may be formed on the first circuit layer 130 and the first plating resist 210. The third plating resist 230 may include a third plating opening part 231 exposing a region on which the post bump 160 is to be formed. The third plating opening part 231 is formed on the bump pad 132.

In addition, a fourth plating resist 240 may be further formed on the second plating resist 220 and the second circuit layer 140. The fourth plating resist 240 may be formed to prevent the plating from being performed on the second plating resist 220 and the second circuit layer 140 when the post bump 160 is formed later on.

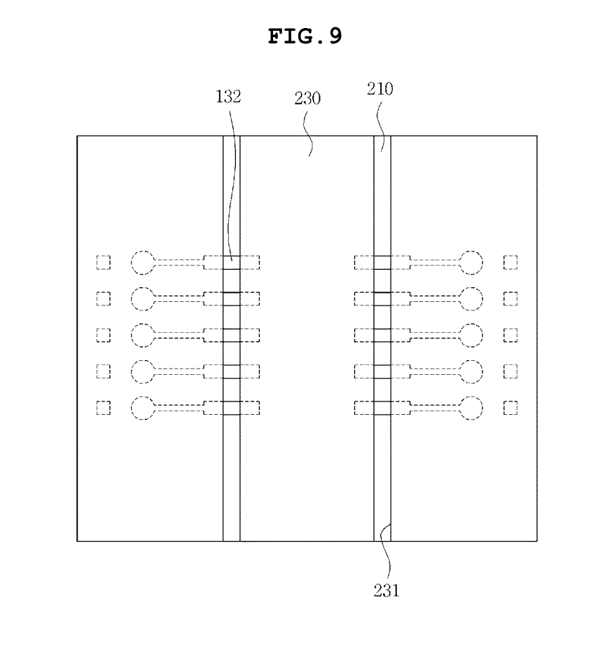

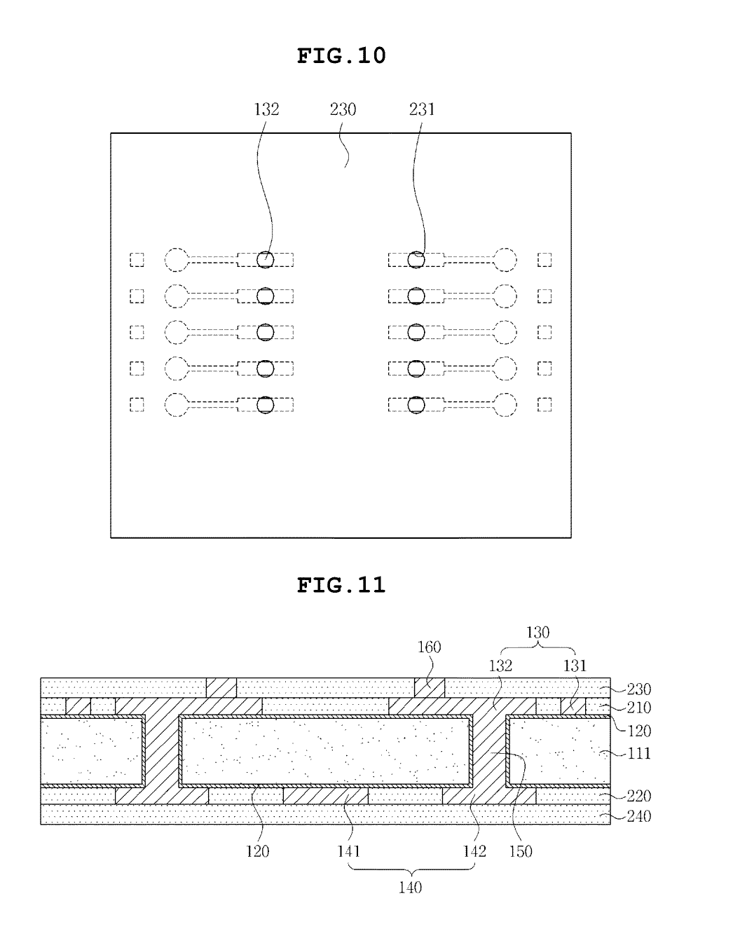

The third plating resist 230 and the fourth plating resist 240 may be formed of a dry film. The third plating opening part 231 may be patterned by exposing and developing the third plating resist 230. In this case, the third plating resist 230 may have the third plating opening part 231 patterned so as to open a plurality of bump pads 132, as shown in FIG. 9. In addition, the third plating resist 230 may have the third plating opening part 231 patterned so as to separately open a plurality of bump pads 132, as shown in FIG. 10. The forms of the third plating opening part 231 of the third plating resist 230 shown in FIGS. 9 and 10 are merely preferred embodiments, the present invention is not limited thereto. That is, the form of the third plating opening part 231 of the third plating resist 230 may be easily changed by those skilled in the art.

Referring to FIG. 11, the post bump 160 may be formed on the bump pad 132 exposed by the third plating opening part 231 (see FIG. 8) of the third plating resist 230. According to a preferred embodiment of the present invention, the post bump 160 may be made of the same material as the first circuit layer 130. In addition, the post bump 160 may be formed by the same method as the first circuit layer 130. For example, in the case in which the first circuit layer 130 is made of a copper material and is formed by the electro plating method, the post bump 160 may also be made of the copper material and be formed by the electro plating method. Therefore, the post bump 160 may be formed integrally with the bump pad 132. The bump pad 132 may be formed to be thicker than a first solder resist layer 170 (see FIG. 15) to be formed later on. That is, the bump pad 132 may be formed to be protruded from the first solder resist layer 170 (see FIG. 15) to be formed later on.

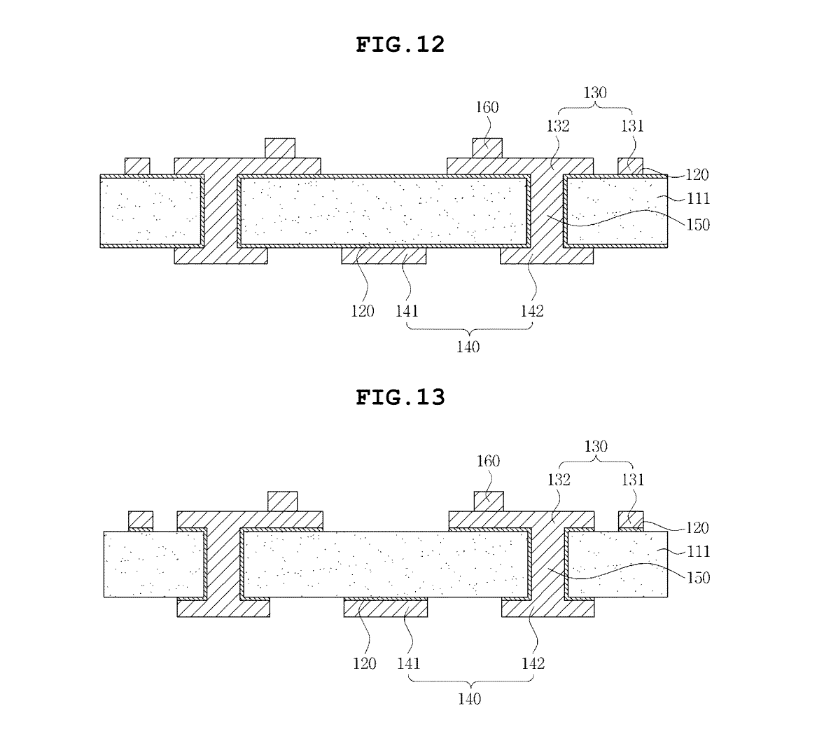

Referring to FIG. 12, the first plating resist 210 (see FIG. 11) to the fourth plating resist 240 (FIG. 11) may be removed. If the first plating resist 210 (see FIG. 11) to the fourth plating resist 240 (FIG. 11) are removed, the seed layer 120 may be exposed. Here, the exposed seed layer 120 is a seed layer 120 formed on a region other than the regions on which the first circuit layer 130 and the second circuit layer 140 are formed.

Referring to FIG. 13, the exposed seed layer 120 may be removed by removing the first plating resist 210 (see FIG. 11) to the fourth plating resist 240 (FIG. 11). For example, the seed layer 120 may be removed by a quick etching method using a strong base such as NaOH or KOH. In addition, the seed layer 120 may be removed by a flash etching method using H₂O₂ or H₂SO₄. A method for removing the seed layer 120 is not particularly limited, but the seed layer 120 may be removed by a typical method known in the art. The insulating layer 111 may be exposed from the region from which the seed layer 120 is removed.

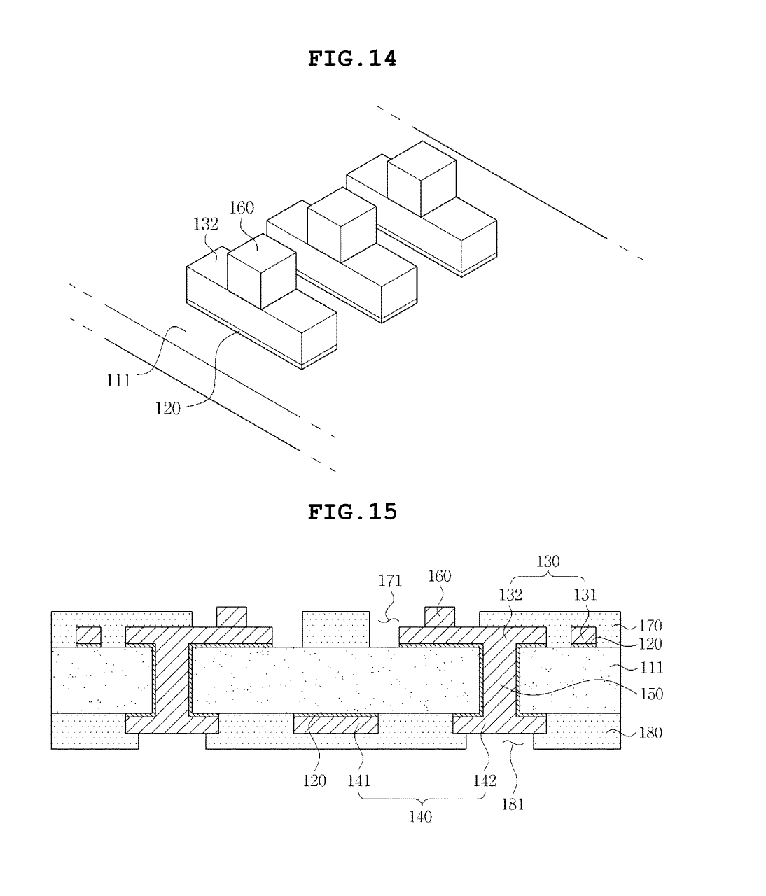

Referring to FIG. 14, the printed circuit board may have a two-layer structure in which the post bump 160 is formed on the bump pad 132 as shown when the seed layer 120 is removed. FIG. 14 illustrates the two-layer structure in which the post bump 160 is formed on the bump pad 132 in detail, wherein a first circuit pattern 131 (see FIG. 13) and other configurations are not shown.

As shown in FIG. 14, the post bump 160 is formed on the bump pad 132, such that a sufficient gap between the semiconductor chip to be mounted later on and the printed circuit board is formed, thereby making it possible to improve flowability of the underfill material. In addition, connection reliability may more improved by the post bump 160 as compared to a case in which the printed circuit board and the semiconductor chip are electrically connected by only a solder according to the prior art. As a result, electrical characteristics between the printed circuit board and the semiconductor chip may also be improved.

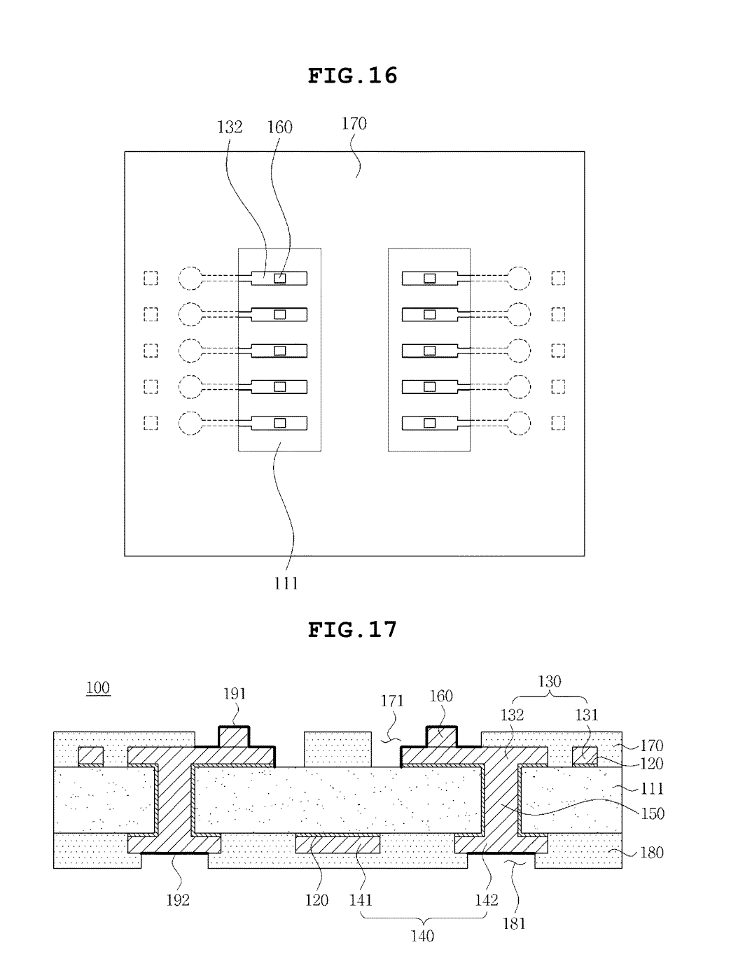

Referring to FIGS. 15 and 16, a first solder resist layer 170 and a second solder resist layer 180 may be formed on the insulating layer 111.

The first solder resist layer 170 and the second solder resist layer 180 may be formed to protect and electrically insulate circuit patterns.

The first solder resist layer 170 may be formed on one surface of the insulating layer 111 and on the first circuit layer 130. The first solder resist layer 170 may be formed to bury the first circuit pattern 131. The first solder resist layer 170 may include a first opening part 171 exposing the post bump 160 to the outside. The first opening part 171 may expose the post bump 160 as well as the bump pad 132 to the outside. A degree of exposing the bump pad 132 by the first opening part 171 may be easily changed by those skilled in the art.

The second solder resist layer 180 may be formed on the other surface of the insulating layer 111 and on the second circuit layer 140. The second solder resist layer 180 may be formed to bury the second circuit pattern 141. The second solder resist layer 180 may include a second opening part 181 exposing the connection pad 142 to the outside.

In this case, the post bump 160 may be protruded from one surface of the first solder resist layer 170. The sufficient gap between the semiconductor chip (not shown) and the semiconductor package board 100 may be secured by the post bump 160 formed as described above, thereby making it possible to improve flowability of the underfill material.

Referring to FIG. 17, a first surface treatment layer 191 and a second surface treatment surface 192 may be formed on the bump pad 132, the post bump 160, and the connection pad 142 which are exposed to the outside.

The first surface treatment layer 191 may be formed on the post bump 160 and the bump pad 132 exposed by the first opening part 171 of the first solder resist layer 170. The second surface treatment layer 192 may be formed on the connection pad 142 exposed by the second opening part 181 of the second solder resist layer 180.

The first surface treatment layer 191 and the second surface treatment layer 192 are not particularly limited as long as they are known in the art. For example, the first surface treatment layer 191 and the second surface treatment layer 192 may be formed by an electro gold plating method, an immersion gold plating method, an organic solderability preservative (OSP) method or an immersion tin plating method, an immersion silver plating method, a direct immersion gold plating (DIG) method, a hot air solder leveling (HASL) method, or the like, for example.

The first surface treatment layer 191 and the second surface treatment layer 192 may be selectively formed by those skilled in the art.

According to the preferred embodiment of the present invention, the semiconductor package board and the method for manufacturing the same may improve flowability of the underfill.

According to the preferred embodiment of the present invention, the semiconductor package board and the method for manufacturing the same may improve connection reliability between the semiconductor chip and the board.

According to the preferred embodiment of the present invention, the semiconductor package board and the method for manufacturing the same may improve electrical characteristics for the high speed signal.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A semiconductor package board comprising:
an insulating layer;
a first circuit layer formed on one surface of the insulating layer and including a bump pad;
a post bump formed on the bump pad and formed integrally with the bump pad; and
a first solder resist layer formed on the insulating layer and the first circuit layer and having a first opening part exposing the post bump and the bump pad formed thereon.

2. The semiconductor package board as set forth in claim 1, wherein the bump pad and the post bump are made of the same material as each other.

3. The semiconductor package board as set forth in claim 1, further comprising a first surface treatment layer formed on the bump pad and the post bump exposed by the first opening part.

4. The semiconductor package board as set forth in claim 1, further comprising a second circuit layer formed on the other surface of the insulating layer and including a connection pad.

5. The semiconductor package board as set forth in claim 4, further comprising a through via penetrating through the insulating layer to electrically connect the first circuit layer and the second circuit layer to each other.

6. The semiconductor package board as set forth in claim 5, wherein the through via electrically connects the bump pad and the connection pad to each other.

7. The semiconductor package board as set forth in claim 4, further comprising a second solder resist layer formed on the other surface of the insulating layer and the second circuit layer and having a second opening part exposing the connection pad formed thereon.

8. The semiconductor package board as set forth in claim 7, further comprising a second surface treatment layer formed on the connection pad exposed by the second opening part.

9. The semiconductor package board as set forth in claim 1, wherein the post bump is formed to be protruded from one surface of the first solder resist layer.

10. A method for manufacturing a semiconductor package board, the method comprising:
preparing an insulating layer;
forming a first circuit layer including a bump pad on one surface of the insulating layer;
fanning a post bump on the bump pad; and
forming a first solder resist layer including a first opening part exposing the post bump and the bump pad.

11. The method as set forth in claim 10, wherein in the forming of the post bump, the post bump is made of the same material as the bump pad.

12. The method as set forth in claim 10, further comprising, after the forming of the first solder resist layer, forming a first surface treatment layer on the bump pad and the post bump exposed by the first opening part.

13. The method as set forth in claim 10, wherein the forming of the first circuit layer further includes forming a second circuit layer including a connection pad on the other surface of the insulating layer.

14. The method as set forth in claim 13, wherein the forming of the first circuit layer further includes forming a through via penetrating through the insulating layer to electrically connect the first circuit layer and the second circuit layer to each other.

15. The method as set forth in claim 14, wherein the through via is formed to electrically connect the bump pad and the connection pad to each other.

16. The method as set forth in claim 13, further comprising, after the forming of the second circuit layer, forming a second solder resist layer formed on the other surface of the insulating layer and the second circuit layer and having a second opening part exposing the connection pad formed thereon.

17. The method as set forth in claim 16, further comprising, after the forming of the second solder resist layer, forming a second surface treatment layer on the connection pad exposed by the second opening part.

18. The method as set forth in claim 14, further comprising, after the forming of the second circuit layer, forming a solder ball on the connection pad.
